(19) United States
(12) Patent Application Publication
(10) Pub. No.: US 2008/0182408 A1
(43) Pub. Date: Jul. 31, 2008

(54) Methods of Forming Carbon Nano-Tube Wires on a Catalyst Metal Layer and Related Methods of Wiring Semiconductor Devices Using Such Carbon Nano-Tube Wires

(75) Inventors: Sun-Woo Lee, Incheon (KR); In-Seok Yeo, Seoul (KR); Jun-Young Lee, Yongin-si (KR); Jung-Hyeon Kim, Hwaseong-si (KR); Hong-Sik Yoon, Seoul (KR); Kyung-Rae Byun, Suwon-si (KR)

Correspondence Address: MYERS BIGEL SIBLEY & SAJOVEC, PO BOX 37428, RALEIGH, NC, 27627, US

(73) Assignee: Samsung Electronics Company, Ltd.

(21) Appl. No.: 11/842,415

(22) Filed: Aug. 21, 2007

(30) Foreign Application Priority Data
Sep. 27, 2006 (KR) 2006-93844

(51) Int. Cl. H01L 21/768

(52) U.S. Cl. 438/675; 257/E21.585; 977/742

(57) ABSTRACT

In a method of forming a carbon nano-tube, an oxidized metal layer is formed on a substrate. An insulation layer having an opening is formed on the oxidized metal layer to expose a surface of the oxidized metal layer through the opening. The oxidized metal layer exposed through the opening is converted into a catalyst metal layer pattern for allowing a carbon nano-tube to grow from the catalyst metal layer pattern. The carbon nano-tube grows from the catalyst metal layer pattern to form a carbon nano-tube wire in the opening. Thus, the carbon nano-tube may not grow between the insulation layer pattern and the catalyst metal layer pattern.

### CROSS-REFERENCE TO RELATED APPLICATIONS

This application claims priority under 35 U.S.C. § 119 from Korean Patent Application No. 2006-93844 filed on Sep. 27, 2006, the disclosure of which is hereby incorporated herein by reference in its entirety.

### FIELD OF THE INVENTION

Embodiments of the present invention relate to semiconductor devices and, more particularly, to methods of forming carbon nano-tube wires and related methods of wiring semiconductor devices using such carbon nano-tube wires.

### BACKGROUND

Semiconductor devices having high data transmission speed are desired for many applications. One way of increasing the data transmission speed of a semiconductor device may be to highly integrate cells in the chips of the semiconductor device. In order to increase the degree of integration of the cells in semiconductor chips, the design rule for the wiring in some chips has been reduced down to a nanometer scale. However, reducing the design rule of the wiring may cause problems including, for example, the generation of hillocks caused by electro-migrations (which may increase the likelihood of cuts in the metal wiring), the need for a diffusion barrier layer in some applications and/or an increase in an exponential functional specific resistance. To overcome these problems, techniques for forming wiring using a carbon nano-tube (CNT) have been investigated.

A CNT has a one-dimensional quantum-wire structure. Further, the CNT has electrical characteristics such as quantum transport in one dimension. A CNT may have a good current density characteristic compared to metal wiring. For example, typical copper wiring may have a transport current density of about 10⁶ A/cm². In contrast, a CNT may have a transport current density of about 10⁹ A/cm² to about 10¹⁰ A/cm². Further, the CNT may have chemical stability as well as mechanical strength.

In addition, the cutting problem caused by the electro-migration may not be generated in the CNT. Further, since the CNT mainly includes carbon, the aforementioned diffusion barrier layers, which may be used to reduce and/or prevent metal in a metal layer from diffusing into a silicon layer, may also not be necessary.

A conventional method of forming wiring for a semiconductor device using a CNT is disclosed in U.S. Pat. No. 7,060,543. As shown in FIG. 1, according to this conventional method, a catalyst metal layer 10 is formed on an electrode in a semiconductor device. An insulation layer 20 is formed on the catalyst metal layer. A contact hole is formed through the insulation layer 20 to partially expose the catalyst metal layer 10 through the contact hole. A source gas including carbon is applied to the catalyst metal layer 10 through the contact hole to grow the CNT from the catalyst metal layer 10, thereby forming a CNT wire 30 in the contact hole. However, as is also shown in FIG. 1, in this conventional method, the CNT may grow between the catalyst metal layer 10 and the insulation layer 20 as well as on the surface of the catalyst metal layer 10. As a result, the insulation layer 20 may be lifted off from the catalyst metal layer 10. That is, interface ruptures may be generated between the insulation layer 20 and the catalyst metal layer 10.

### SUMMARY

Example embodiments of the present invention provide methods of forming carbon nano-tube wires as well as methods of forming wiring for semiconductor devices using such methods.

In certain embodiments of the present invention, an oxidized metal layer is formed on a substrate. An insulation layer having an opening is formed on the oxidized metal layer to expose a surface of the oxidized metal layer through the opening. The oxidized metal layer exposed through the opening is converted into a catalyst metal layer pattern. A carbon nano-tube is grown from the catalyst metal layer pattern to form a carbon nano-tube wire in the opening.

In some embodiments, the oxidized metal layer may be obtained by forming a metal layer on the substrate, and by oxidizing the metal layer under an oxygen gas atmosphere that includes at least one oxygen containing gas. The metal layer may be formed by a chemical vapor deposition (CVD) process, a physical vapor deposition (PVD) process, an atomic layer deposition (ALD) process, etc. Alternatively, the oxidized metal layer may be formed by a CVD process or a PVD process using metal oxide.

In certain embodiments, the catalyst metal layer pattern may be formed by reducing the oxidized metal layer at a temperature of about 500° C. to about 800° C. under a hydrogen gas atmosphere. In some embodiments, the catalyst metal layer pattern and the carbon nano-tube wire may be formed in a single chamber by an in-situ process.

In certain embodiments, the carbon nano-tube wire may be formed by reducing the oxidized metal layer at a temperature of about 500° C. to about 800° C. under a hydrogen atmosphere to form the catalyst metal layer pattern by applying a hydrocarbon gas to the catalyst metal layer pattern to thermally decompose the hydrocarbon gas, thereby generating carbon. The carbon nano-tube wire may be formed by growing the carbon nano-tube from the surface of the catalyst metal layer pattern using the carbon.

In a method of forming a wiring of a semiconductor device in accordance with another aspect of the present invention, a metal layer is formed on a substrate on which a conductive pattern is formed. The metal layer is oxidized to form an oxidized metal layer from which a carbon nano-tube does not grow. An insulation interlayer is then formed on the oxidized metal layer. The insulation interlayer is patterned to form an insulation interlayer pattern having an opening that exposes a surface of the oxidized metal layer. The oxidized metal layer exposed through the opening is converted into a catalyst metal layer pattern for allowing the carbon nano-tube to grow from the catalyst metal layer pattern. The carbon nano-tube grows from the catalyst metal layer pattern to form a carbon nano-tube wire in the opening. A conductive wire is formed on the insulation interlayer pattern to electrically connect the conductive wire to the carbon nano-tube wire.

According to embodiments of the present invention, the carbon nano-tube may grow only from the catalyst metal layer pattern so that interface ruptures may not be generated by forming the carbon nano-tube wire. That is, since the carbon nano-tube having conductive characteristics may not be formed under the insulation layer pattern, the insulation layer pattern may not be lifted off from the substrate. Further, the carbon nano-tube wire may have desired profiles.

### BRIEF DESCRIPTION OF THE DRAWINGS

The above and other features and advantages of the present invention will become more apparent by describing in detail certain embodiments thereof with reference to the accompanying drawings, in which:

FIG. 1 is a cross-sectional view illustrating a conventional method of forming a carbon nano-tube wire;

FIGS. 2 to 5 are cross-sectional views illustrating methods of forming carbon nano-tube wires in accordance with first embodiments of the present invention;

FIGS. 6 to 12 are cross-sectional views illustrating methods of forming wiring of a semiconductor device in accordance with second embodiments of the present invention;

FIG. 13 is an electron microscopic picture showing a carbon nano-tube formed in Experiment 1; and

FIG. 14 is an electron microscopic picture showing a carbon nano-tube formed in Experiment 2.

### DETAILED DESCRIPTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

### EMBODIMENT 1

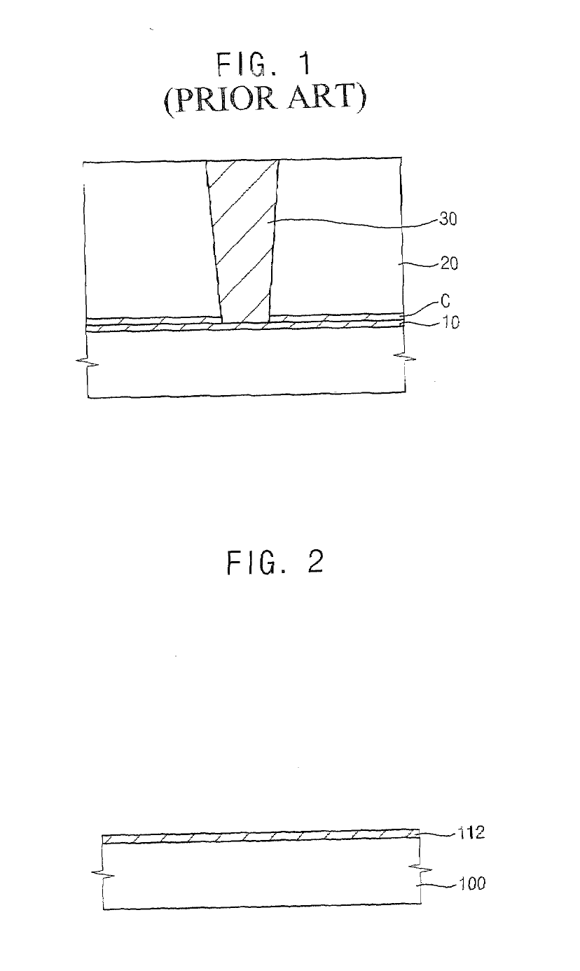

FIGS. 2 to 5 are cross-sectional views illustrating methods of forming carbon nano-tube wires in accordance with first embodiments of the present invention.

Referring to FIG. 2, an oxidized metal layer 112 is formed on a substrate 100. The substrate 100 may include an insulation material such as silicon, silicon oxide, silicon nitride, etc. Alternatively, the substrate 100 may comprise a conductive material such as a metal, a metal alloy, doped polysilicon, etc.

Additionally, a structure (not shown) and an insulation interlayer (not shown) for insulating the structure may also be formed on the substrate 100. Examples of such structures include a transistor, a contact pad of a capacitor that is electrically connected to a contact region of a transistor, a bit line that is electrically connected to a contact region of a transistor, a capacitor, etc.

The oxidized metal layer 112 may be obtained by, for example, forming a metal layer (not shown) on the substrate 100, and by oxidizing the metal layer under an oxygen gas atmosphere. The oxidized metal layer 112 may have a thickness of about 5 Å to about 40 Å. The metal layer may be formed, for example, by depositing a metal such as, for example, manganese (Mn), iron (Fe), cobalt (Co), nickel (Ni), ruthenium (Ru), yttrium (Y), nickel-iron (Ni—Fe), cobalt-iron (Co—Fe), nickel-cobalt-iron (Ni—Co—Fe), etc. on the substrate using a chemical vapor deposition (CVD) process, a physical vapor deposition (PVD) process, an atomic layer deposition (ALD) process, etc. The oxidized metal layer 112 may be formed by thermally oxidizing the metal layer at a temperature of, for example, about 300° C. to about 600° C. under an oxygen gas atmosphere to convert the metal layer into metal oxide. The oxygen gas may include, for example, an oxygen gas, an ozone gas, a vapor, an activated oxygen gas, an activated ozone gas, etc. The oxygen gas atmosphere may also include other non-oxygen-containing gases. Examples of the metal oxide may include nickel oxide, cobalt oxide, yttrium oxide, iron oxide, nickel-iron oxide, cobalt-iron-oxide, nickel-cobalt-iron oxide, etc.

Alternatively, the oxidized metal layer 112 may be obtained by depositing metal oxide on the substrate 100. The metal oxide may be deposited by a CVD process, a PVD process, etc.

Here, the oxidized metal layer 112 has characteristics contrary to those of the metal layer that serves as a catalyst for growing a carbon nano-tube (CNT). Thus, the CNT may not grow from the oxidized metal layer 112.

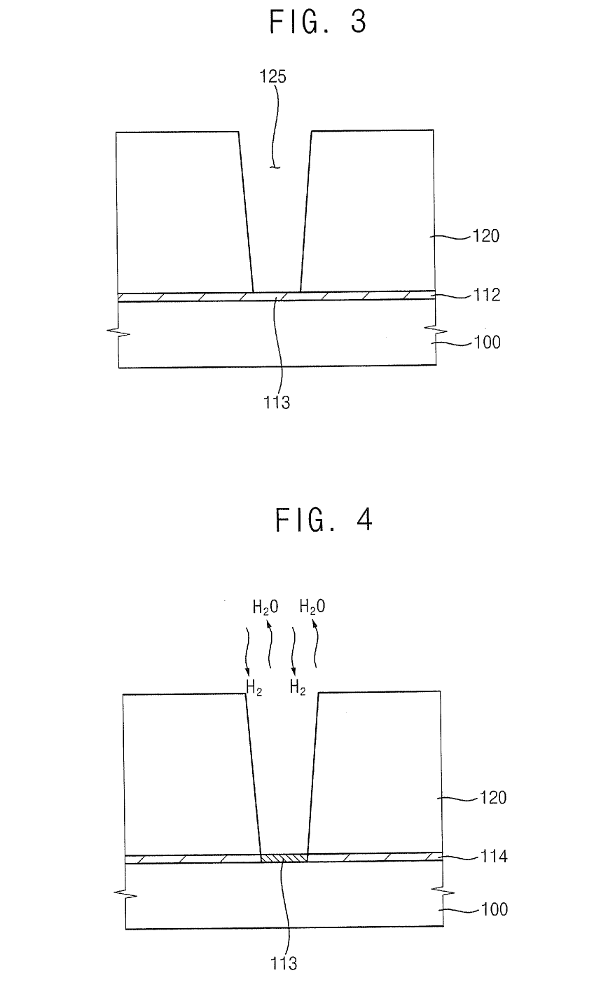

Referring to FIG. 3, an insulation layer pattern 120 is formed on the oxidized metal layer 112. The insulation layer pattern 120 has an opening 125 that exposes an upper face of the oxidized metal layer 120.

In some embodiments of the present invention, the insulation layer pattern 120 may be formed by forming an insulation layer (not shown) on the oxidized metal layer 112. This insulation layer may include, for example, silicon oxide. For example, in some embodiments, the insulation layer may comprise phosphor silicate glass (PSG), boro-phosphorous silicate glass (BPSG), undoped silica glass (USG), spin-on-glass (SOG), tetra-ethyl-ortho-silicate (TEOS), plasma enhanced TEOS (PE-TEOS), etc. The insulation layer may be formed, for example, by a CVD process, a plasma-enhanced CVD (PECVD) process, a high density CVD (HDCVD) process, a spin coating process, etc.

Next, a photoresist pattern (not shown) for defining a region where the opening 125 is formed is formed on the insulation layer. The insulation layer is then etched using the photoresist pattern as an etching mask to form the insulation layer pattern 120 having the opening 125 on the oxidized metal layer 112. After forming the insulation layer pattern 120, the photoresist pattern may then be removed by, for example, an ashing process using oxygen plasma and/or a stripping process.

Referring to FIG. 4, the oxidized metal layer 112 exposed through the opening 125 is converted into a catalyst metal layer pattern 113. Herein, a “catalyst metal layer pattern” refers to a metal layer pattern from which a carbon nano-tube wire may be readily grown. Further, the oxidized metal layer 112 is converted into an oxidized metal layer pattern 114 simultaneously with the formation of the catalyst metal layer pattern 113.

In some embodiments of the present invention, the catalyst metal layer pattern 113 may be formed by reducing the oxidized metal layer 112 exposed through the opening 125 under a reduction gas including hydrogen. This may be accomplished, for example, by loading the substrate 100 having the oxidized metal layer 112 and insulation layer pattern 120 thereon into a process chamber and then introducing the reduction gas into the process chamber at a temperature of about 500° C. to about 800° C. The reduction gas may comprise, for example, a hydrogen gas.

As shown in FIG. 4, the oxidized metal layer pattern 114 is positioned between the substrate 100 and the insulation layer pattern 120. Therefore, the oxidized metal layer pattern 114 may not be exposed through the opening 125. In contrast, the catalyst metal layer pattern 113 is exposed through the opening 125.

For example, when the oxidized metal layer pattern 112 includes nickel oxide, a mechanism for forming a nickel layer from the nickel oxide layer so as to use it as the catalyst metal layer pattern 113 is illustrated in detail.

The nickel oxide layer includes nickel oxide (NiOₓ). Thus, when hydrogen gas is applied as a reduction gas to the nickel oxide layer at a temperature of about 500° C. to about 800° C., oxygen in the nickel oxide layer chemically reacts with hydrogen in the hydrogen gas to generate a vapor (H₂O). The nickel oxide is thus reduced by the hydrogen gas to form the nickel layer.

NiOx+xH₂→Ni+^{x}H₂O

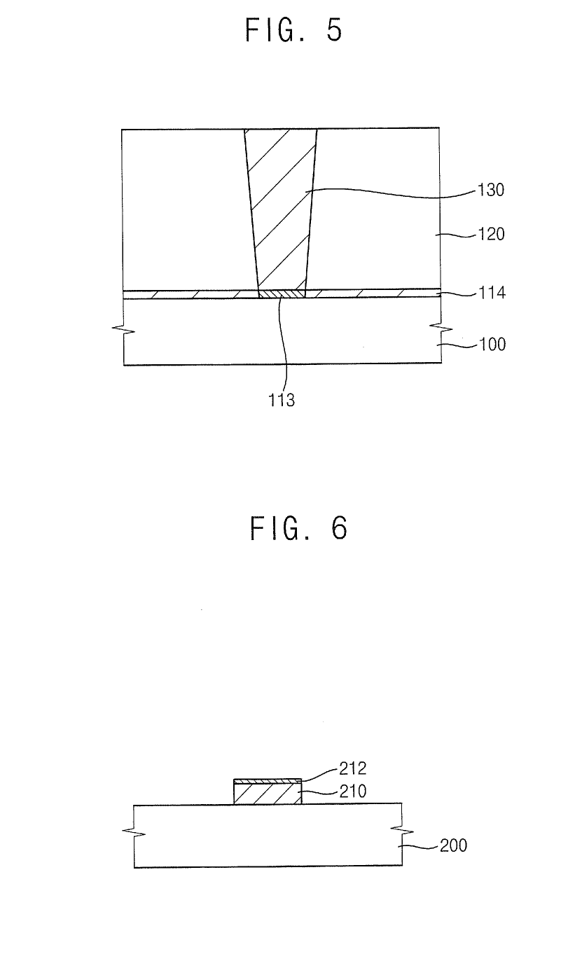

As shown in FIG. 5, a CNT may be grown from the catalyst metal layer pattern 113 to form the CNT wire 130 in the opening 125. In some embodiments of the present invention, a source gas for forming the CNT may be applied to the catalyst metal layer pattern 113 that is exposed through the opening 125 to grow the CNT from the exposed surface of the catalyst metal layer pattern 113. As a result, a CNT wire 130 that is connected to the catalyst metal layer pattern 113 is formed in the opening 125.

The CNT may be formed, for example, by a CVD process. Examples of the CVD process may include a sub-atmospheric CVD process, a low pressure CVD process, a plasma-enhanced CVD process, a thermal CVD process, an electron cyclone resonance CVD process, etc. In some embodiments of the present invention, the CNT may be formed by the CVD process at a temperature of about 500° C. to about 800° C. under a pressure of about 0.1 Torr to about 10 Torr.

When the growth of the CNT is carried out at a temperature below about 500° C., a relatively small amount of carbon may be solved in the catalyst metal layer pattern 113 due to low energy supplied therein. Thus, the CNT may not grow efficiently. In contrast, when the CNT grows at a temperature above about 800° C., the CNT may melt because of intense heat supplied thereto. Further, thermal stresses may be excessively applied to an underlying structure of the substrate 100. Therefore, the CNT may be advantageously formed at a temperature below about 500° C. to about 800° C. Likewise, when the CNT grows at a pressure below about 0.1 Torr, the CNT may grow slowly. In contrast, when the CNT grows at a pressure above about 10 Torr, the growth speed of the CNT may not be effectively controlled. Thus, in some embodiments, the CNT may be grown at a pressure of between about 0.1 Torr and about 10 Torr. For example, the CNT may grow in a pressure of about 5 Torr.

However, it will be appreciated that the CNT may be grown at other temperatures and/or pressures without departing from the teachings of the present invention.

The source material for forming the CNT may include a carbonization gas. Examples of the carbonization gas may include a methane gas, an acetylene gas, an ethyl alcohol gas, a carbon monoxide gas, etc.

When a CVD process using the carbonization gas is carried out, the carbonization gas is thermally decomposed to generate carbon and hydrogen. The carbon and the hydrogen are introduced into the opening 125. The carbon in the opening 125 is chemisorbed on the catalyst metal layer pattern 113 to grow the CNT continuously. As a result, the CNT wire 130 connected to the catalyst metal layer pattern 113 is formed in the opening 125.

An etching process for removing a portion of the CNT that is grown from the surface of the catalyst metal layer pattern 113 may also be carried out. Examples of the etching process may include an etch-back process, a chemical mechanical polishing (CMP) process, etc.

Although not shown in the figures, the processes for forming the catalyst metal layer pattern 113 and for forming the CNT wire 130 may be carried out in a single chamber by an in-situ process. For example, in some embodiments of the present invention, a hydrogen gas is introduced into the process chamber as a reduction gas at a temperature of about 500° C. to about 800° C. The exposed portion of the oxidized metal layer 112 is then reduced using the hydrogen gas to convert the exposed portion of the oxidized metal layer 112 into a catalyst metal layer pattern 113. The carbonization gas and the hydrogen gas are introduced into the process chamber to thermally decompose the carbonization gas. The CNT grows from the surface of the catalyst metal layer pattern 113 using the carbon generated from the thermally decomposed carbonization gas to form the CNT wire 130 in the opening 125.

According to this example embodiment of the present invention, while the CNT wire 130 grows from the catalyst metal layer pattern 113, the CNT may not be formed on the oxidized metal layer pattern 114 that makes contact with the insulation layer pattern 120. Thus, the insulation layer pattern 120 may not be lifted off from the oxidized metal layer pattern 114.

### EMBODIMENT 2

FIGS. 6 to 12 are cross-sectional views illustrating methods of forming carbon nano-tube wires in accordance with second embodiments of the present invention.

As shown in FIG. 6, a conductive pattern 210 is formed on a substrate 200. The conductive pattern 210 may include a switching element that functions so as to receive a signal from an exterior source (i.e., another part of the semiconductor device) and to transmit the signal to a phase-changeable memory cell. Examples of the switching element may include a diode, a transistor such as a MOSFET, etc. In this example embodiment of the present invention, a diode is used as the switching element.

A metal layer (not shown) is then formed on the conductive pattern 210. The metal layer is oxidized and patterned (either before, during or after oxidation) to form an oxidized metal layer pattern 212. The oxidized metal layer pattern 212 may be formed, for example, by thermally oxidizing the metal layer at a temperature of about 300° C. to about 600° under an oxygen gas atmosphere.

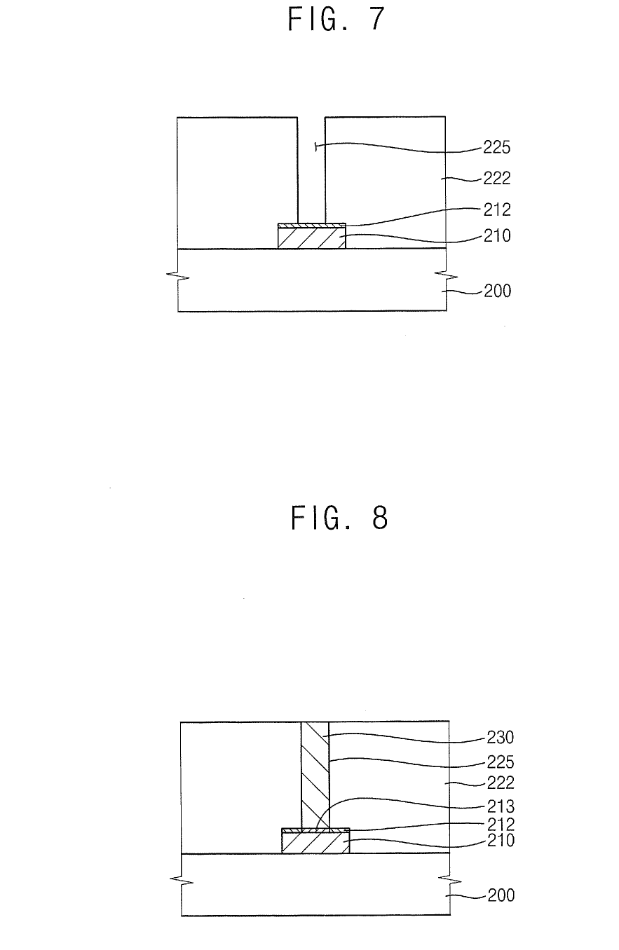

Referring to FIG. 7, a first insulation layer (not shown) may be formed that covers the conductive pattern 210 having the oxidized metal layer pattern 212. The first insulation layer may include silicon oxide. For example, the first insulation layer may include phosphor silicate glass (PSG), boro-phosphorous silicate glass (BPSG), undoped silica glass (USG), spin-on-glass (SOG), tetra-ethyl-ortho-silicate (TEOS), plasma-enhanced TEOS (PE-TEOS), etc.

An etching mask (not shown) may then be formed on the first insulation layer to define a region where a first contact hole 225 will be formed. The first insulation layer is then etched using the etching mask to form a first insulation layer pattern 222 having the first contact hole 225. After forming the first insulation layer pattern 222, the etching mask may be removed by, for example, an ashing process and/or a stripping process.

Referring to FIG. 8, the oxidized metal layer 212 exposed through the first contact hole 225 is reduced under a hydrogen gas atmosphere to form a catalyst metal layer pattern 213 from which the CNT can grow. In some embodiments of the present invention, the reduction process may include loading the substrate 200 on which the first insulation layer pattern 222 is formed into a process chamber and then introducing a reduction gas into the process chamber at a temperature of about 500° C. to about 800° C. The reduction gas may include, for example, a hydrogen gas, a carbonization gas, a combination gas thereof, etc.

A source gas for forming the CNT is then applied to the catalyst metal layer pattern 213 that is exposed through the first contact hole 225 to grow the CNT from the exposed surface of the catalyst metal layer pattern 213. As a result, a CNT wire 230 that is connected to the catalyst metal layer pattern 213 is formed in the first contact hole 225.

In some embodiments of the present invention, the CNT may be formed by a PECVD process at a temperature of about 500° C. to about 800° C. under a pressure of about 0.1 Torr to about 10 Torr. Further, the catalyst metal layer pattern 213 and the CNT wire 230 may be formed in a single chamber by an in-situ process.

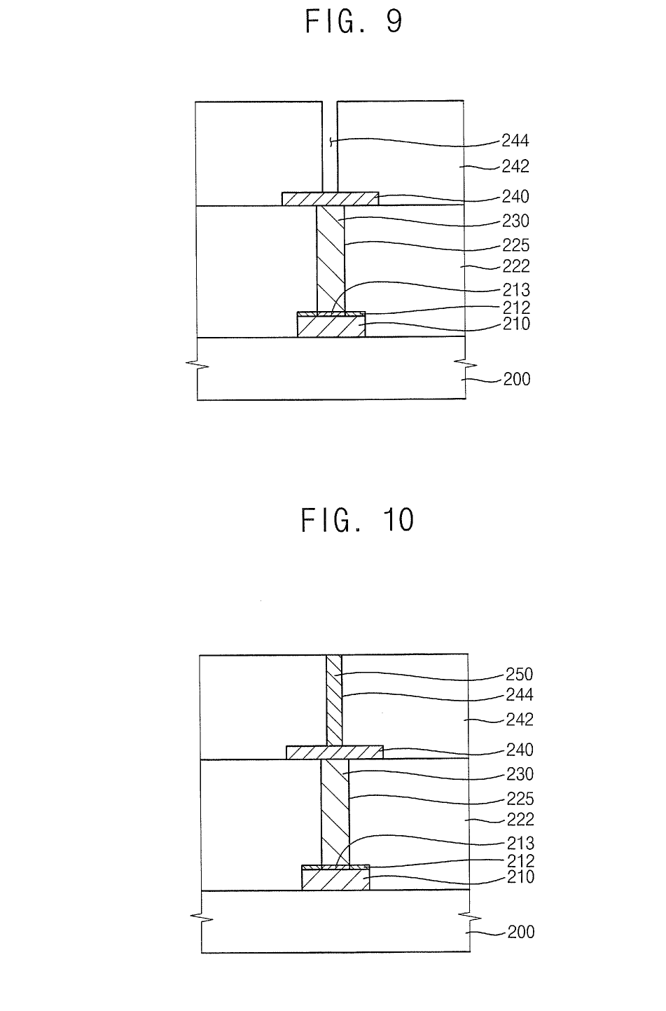

Referring to FIG. 9, a conductive wiring element 240 that is electrically connected to the CNT wire 230 is formed on the first insulation interlayer pattern 222. The conductive wiring element 240 may include a first conductive material such as, for example, titanium nitride, titanium, tantalum, tungsten, aluminum, copper, etc. In this example embodiment of the present invention, the conductive wiring element 240 may correspond to the lower electrode pad of a phase-changeable memory cell.

Referring to FIG. 10, a second insulation interlayer (not shown) is formed on the first insulation interlayer pattern 222 having the lower electrode pad 240 to cover the lower electrode pad 240. The second insulation interlayer is patterned to form a second insulation interlayer 242 having a second contact hole 244 that exposes an upper face of the lower electrode pad 240. A lower electrode 250 is formed in the second contact hole 244. The lower electrode 250 is electrically connected to the lower electrode pad 240. The lower electrode 250 may be formed, for example, by forming a conductive layer (not shown) on the second insulation interlayer pattern 242 and in the second contact hole 244. Upper portions of the conductive layer may be removed, for example, by a chemical-mechanical polishing (CMP) process that exposes an upper face of the second insulation interlayer 242 to form the lower electrode 250 in the second contact hole 244.

The lower electrode 250 may include a second conductive material that generates heat when a current is applied to the lower electrode 250. Further, the lower electrode 250 may include a conductive material having good gap-filling characteristics. Examples of the second conductive material may include tungsten, titanium, titanium nitride, tantalum, tantalum nitride, molybdenum nitride, niobium nitride, titanium silicon nitride, aluminum, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, etc. These can be used alone or in combinations thereof.

Although not shown in the figures, for example, when a photolithography process margin for forming the second contact hole 244 may be insufficient, a spacer (not shown) may be additionally formed on an inner face of the second contact hole 244 to provide the lower electrode 250 with a width narrower than a diameter of the second contact hole 244.

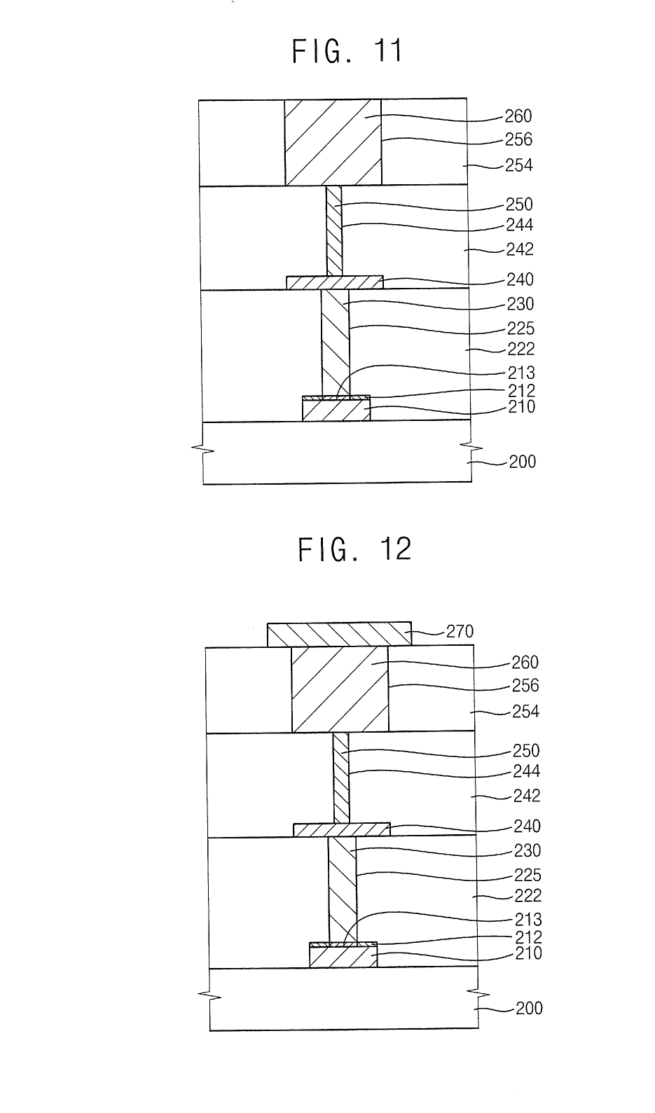

Referring to FIG. 11, a third insulation interlayer (not shown) may be formed on the lower electrode 250 and the second insulation interlayer pattern 242. The third insulation interlayer may be formed, for example, by a CVD process, a PECVD process, etc. The third insulation interlayer is then patterned to form a third insulation interlayer 254 having an opening 256 that defines a region where, for example, a phase-changeable memory cell may be formed.

A phase-changeable material layer pattern 260 is then formed in the opening 256. The phase-changeable material layer pattern 260 may include a chalcogenide compound that has phases that are shifted by heat. For example, the phase-changeable material layer pattern 260 may be formed using the chalcogenide compound that includes germanium-antimony-tellurium (GeSbTe; GST), arsenic-antimony-tellurium (AsSbTe), tin-antimony-tellurium (SnSbTe), tin-indium-antimony-tellurium (SnInSbTe), or arsenic-germanium-antimony-tellurium (AsGeSbTe). Alternatively, the phase-change material may be formed using a compound that includes (an element from Group 5)-antimony-tellurium. Here, the element from Group 5 may be an element such as tantalum, niobium or vanadium. In still other embodiments, the phase-change material may be formed using a compound that includes (an element from Group 6)-antimony-tellurium. Here, the element from Group 6 may be an element such as tungsten, molybdenum or chromium, a compound that includes an element in Group 5-antimony-selenium, or a compound that includes (an element in Group 6)-antimony-selenium. In some specific embodiments of the present invention, the chalcogenide compound may include germanium-antimony-tellurium.

The phase-changeable material layer pattern 260 may have a structure that is changed from an amorphous structure to a crystalline structure and vice versa in accordance with a size and/or a shape of an applied voltage. As such, the phase-changeable material layer pattern 260 has a variable resistance so that the phase-changeable material layer pattern 260 stores or reads data in accordance with current values transmitted through the phase-changeable material layer pattern 260.

Referring to FIG. 12, an upper electrode 270 is electrically connected to the phase-changeable material layer pattern 260. The upper electrode 270 may be formed, for example, by forming an upper electrode layer (not shown) having a generally uniform thickness on the phase-changeable material layer pattern 260 and the third insulation interlayer pattern 254. The upper electrode layer may then be patterned to form the upper electrode 270 that is electrically connected to the phase-changeable material layer pattern 260.

Examples of a conductive material that may be used for the upper electrode 270 may include tungsten, titanium, titanium nitride, tantalum, tantalum nitride, molybdenum nitride, niobium nitride, titanium silicon nitride, aluminum, titanium aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum silicon nitride, tantalum aluminum nitride, etc. These can be used alone or in combinations thereof.

In the specific embodiments of the present invention described above with reference to FIGS. 6-12, methods of forming wiring for a phase-changeable memory device (PRAM) are disclosed. However, it will be appreciated that in other embodiments the same techniques may be used to form wiring for other memory devices such as DRAM, SRAM, MRAM, etc., as well as the PRAM. Further, the semiconductor memory device may further include various transistors as the switching element as well as the diode.

Hereinafter, methods of forming the CNT wire in accordance with the present invention will be described in more detail with respect to two Experiments. It will be appreciated, however, that these Experiments are exemplarily and do not limit the scope of the present invention.

### EXPERIMENT 1

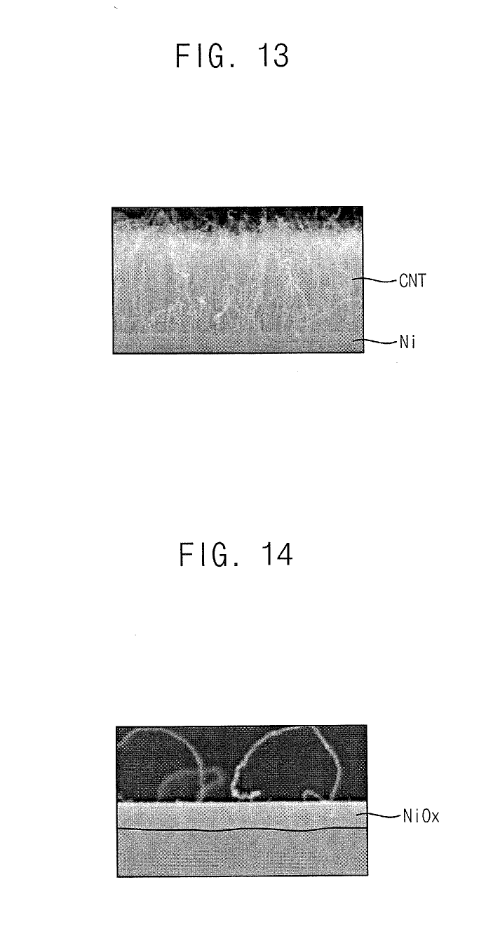

Substrates on which a nickel oxide layer was formed were prepared. Nickel oxide in the nickel oxide layer was reduced at a temperature of 600° C. in a hydrogen atmosphere to form a nickel layer on the substrate. A plasma-enhanced chemical vapor deposition (PECVD) process was carried out on the nickel layer by using a hydrogen gas and a methane gas at a temperature of 600° C. under a pressure of 5 Torr in order to grow a CNT from the nickel layer. The obtained CNT is shown in the electron microscopic photograph of FIG. 13. As shown in FIG. 13, a the CNT having a relatively large density is formed due to good growth of the CNT from the nickel layer as a catalyst metal.

### EXPERIMENT 2

Substrates on which a nickel oxide layer was formed were prepared. A PECVD process using a nitrogen gas and a methane gas at a temperature of 650° C. under a pressure of 5 Torr was carried out on the nickel oxide layer to thereby grow a CNT from the nickel oxide layer. The obtained CNT was shown in the electron microscopic photograph of FIG. 14. As shown in FIG. 14, the nickel oxide layer formed by oxidizing a nickel layer as a catalyst metal does not have the same characteristics as the catalyst metal. Therefore, it can be noted that the CNT rarely grows from the nickel oxide layer.

According to embodiments of the present invention, a carbon nano-tube may grow only from the catalyst metal layer pattern so that interface ruptures that may occur during formation of the CNT wire may be reduced or eliminated. That is, since the carbon nano-tube having conductive characteristics may not be formed under the insulation layer pattern, the insulation layer pattern may not be lifted off from the substrate. Further, the carbon nano-tube wire may have desired profiles. The methods according to embodiments of the present invention may also improve a yield for manufacturing the carbon nano-tube wire. Moreover, additional complicated processes may not be required in the method according to embodiments of the present invention. Therefore, the source gas for the carbon nano-tube may not be wasted.

Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of forming a carbon nano-tube wire, the method comprising:
forming an oxidized metal layer on a substrate;
forming an insulation layer pattern on the oxidized metal layer, the insulation layer pattern having an opening that exposes a surface of the oxidized metal layer;
converting at least a portion of the oxidized metal layer exposed through the opening into a catalyst metal layer pattern; and
growing the carbon nano-tube from the catalyst metal layer pattern to form the carbon nano-tube wire in the opening.

2. The method of claim 1, wherein forming the oxidized metal layer comprises:
forming a metal layer on the substrate; and
oxidizing the metal layer under an oxygen gas atmosphere.

3. The method of claim 2, wherein the metal layer is formed by a chemical vapor deposition (CVD) process, a physical vapor deposition (PVD) process or an atomic layer deposition (ALD) process.

4. The method of claim 2, wherein the metal layer is oxidized at a temperature of about 300° C. to about 600° C., and wherein the oxidized metal layer has a thickness of between about 5 Å to about 40 Å.

5. The method of claim 1, wherein the oxidized metal layer comprises nickel oxide, cobalt oxide, yttrium oxide, iron oxide, nickel-iron oxide, cobalt-iron oxide, nickel-cobalt-iron oxide or combinations thereof.

6. The method of claim 1, wherein forming the oxidized metal layer comprises depositing metal oxide by a chemical vapor deposition (CVD) process or a physical vapor deposition (PVD) process to form the oxidized metal layer.

7. The method of claim 1, wherein forming the catalyst metal layer pattern comprises reducing the oxidized metal layer at a temperature of about 500° C. to about 800° C. under a hydrogen gas atmosphere.

8. The method of claim 7, wherein the hydrogen gas atmosphere comprises a molecular hydrogen (H₂) gas.

9. The method of claim 1, wherein the catalyst metal layer pattern and the carbon nano-tube wire are formed in a single chamber by an in-situ process.

10. The method of claim 7, wherein growing the carbon nano-tube from the catalyst metal layer pattern to form the carbon nano-tube wire in the opening comprises:
thermally decomposing a hydrocarbon gas; and
growing the carbon nano-tube from a surface of the catalyst metal layer pattern using carbon generated from the thermally decomposed hydrocarbon gas as a carbon source.

11. The method of claim 1, wherein the carbon nano-tube is formed by an atmospheric CVD process, a plasma-enhanced PECVD process, a thermal CVD process or an electron cyclone resonance CVD process.

12. The method of claim 1, wherein converting at least a portion of the oxidized metal layer exposed through the opening into a catalyst metal layer pattern and growing the carbon nano-tube from the catalyst metal layer pattern to form the carbon nano-tube wire in the opening comprise reducing the oxidized metal layer at a temperature of about 500° C. to about 800° C. using hydrogen from a thermally decomposed hydrocarbon gas that is applied to the catalyst metal layer pattern, and growing the carbon nano-tube from the surface of the catalyst metal layer pattern using the carbon from the thermally decomposed hydrocarbon gas to form the carbon nano-tube wire in the opening.

13. A method of forming a conductive wiring element of a semiconductor device, comprising:
forming a metal layer on a substrate that includes a conductive pattern;
oxidizing the metal layer to form an oxidized metal layer;
forming a first insulation interlayer on the oxidized metal layer;
patterning the first insulation interlayer to form a first insulation interlayer pattern having a contact hole that exposes at least part of a surface of the oxidized metal layer;
converting the oxidized metal layer exposed through the contact hole into a catalyst metal layer pattern;
growing a carbon nano-tube from the catalyst metal layer pattern to form a carbon nano-tube wire in the contact hole; and
forming the conductive wiring element on the first insulation interlayer, the conductive wiring element being electrically connected to the carbon nano-tube wire.

14. The method of claim 13, wherein the metal layer is oxidized at a temperature of about 300° C. to about 600° C. under an oxygen gas atmosphere, and wherein the oxidized metal layer has a thickness of between about 5 Å to about 40 Å.

15. The method of the claim 13, wherein the conductive wiring element comprises titanium nitride, titanium, tantalum, tungsten, aluminum or copper.

16. The method of claim 13, wherein the substrate that includes the conductive pattern comprises the substrate with the conductive pattern formed on the substrate.

17. The method of claim 16, wherein the conductive pattern includes a switching element.

18. The method of claim 13, wherein the oxidized metal layer comprises nickel oxide, cobalt oxide, yttrium oxide, iron oxide, nickel-iron oxide, cobalt-iron oxide, nickel-cobalt-iron oxide or combinations thereof.

19. The method of claim 13, wherein converting the oxidized metal layer exposed through the contact hole into the catalyst metal layer pattern comprises reducing the exposed oxidized metal layer at a temperature of about 500° C. to about 800° C. under a hydrogen gas atmosphere.

20. The method of claim 13, wherein growing the carbon nano-tube from the catalyst metal layer pattern to form the carbon nano-tube wire in the contact hole comprises:
thermally decomposing a hydrocarbon gas; and
growing the carbon nano-tube from a surface of the catalyst metal layer pattern using carbon generated from the thermally decomposed hydrocarbon gas as a carbon source.

21. The method of claim 13, the method further comprising:
forming a second insulation interlayer on the first insulation interlayer pattern and on the conductive wiring element;
patterning the second insulation interlayer to form a second insulation interlayer pattern that includes a second contact hole that exposes a surface of the conductive wiring element; and
forming a first electrode in the second contact hole that is electrically connected to the conductive wiring element.

22. The method of claim 21, further comprising forming a spacer in the second contact hole prior to forming the first electrode in the second contact hole.

23. The method of claim 21, further comprising:
forming a third insulation interlayer on the first electrode and on the second insulation interlayer pattern;
patterning the third insulation interlayer to form a third insulation interlayer pattern having an opening;
forming a phase-changeable material layer pattern in the opening; and
forming an upper electrode on the phase-changeable material layer pattern that is electrically connected to the phase-changeable material layer pattern.
